(19) United States
(12) Patent Application Publication
(10) Pub. No.: US 2015/0217596 A1
(43) Pub. Date: Aug. 6, 2015

(54) Method for Producing a Non-All-Ceramic Surface

(71) Applicant: Hella KGaA Hueck & Co., Lippstadt (DE)

(72) Inventors: Tobias Heine, Lippstadt (DE); Joachim Olk, Lippstadt (DE); Daniel Reckers, Lippstadt (DE)

(21) Appl. No.: 14/421,112

(22) PCT Filed: Aug. 13, 2013
(86) PCT No.: PCT/EP2013/066891

§ 371 Date: Feb. 11, 2015

(30) Foreign Application Priority Data
Aug. 14, 2012 (DE) 10 2012 107 440.2

(51) Int. Cl. B44F 11/06; C23C 16/27; C23C 14/14; C23C 14/24; C23C 14/02; C23C 14/06; C23C 16/02; C23C 16/06

(52) U.S. Cl. CPC B44F 11/06; C23C 16/0254; C23C 16/0272; C23C 16/27; C23C 16/06; C23C 14/24; C23C 14/028; C23C 14/024; C23C 14/0611; C23C 14/14

(57) ABSTRACT

A method of producing a ceramic-like surface (22) with sensory properties of the ceramic material on a substrate 10, comprising the following steps:
Preparing at least one surface (12) of the substrate (10),
Coating the prepared substrate surface (12) with a ceramic-like sensory layer (20) using a vapor-phase deposition method.

### CROSS REFERENCE

This application claims priority to PCT/EP2013/066891, filed Aug. 13, 2013, which itself claims priority to German Application No. 10 2012 107 440.2, filed Aug. 14, 2012, which are both hereby incorporated by reference.

### FIELD OF TECHNOLOGY

The present invention relates to a method for producing a ceramic-like surface, a method for adapting a vapor-phase deposition method for producing a ceramic-like surface and to a corresponding use of these methods for the production of a mobile component.

### BACKGROUND

Methods for the production of surfaces are in principle known. By this methods are produced and refined, for example, surfaces for mobile components, such as cellular phones, remote controls or motor vehicle keys. In known mobile components this often comprises metallization, in particular with chrome. In this way, a refinement and thus an increase in the qualitative appearance of these mobile devices is performed.

For vehicles, in addition to metallized coatings, is now also used ceramic material as a decorative material. In the situation of application within a vehicle, ceramics is well suitable with respect to its mechanical properties. However, it is not yet possible to use ceramics also in mobile components, because the mechanical properties of ceramics or ceramic material do not meet the requirements of mobile devices. In particular, the danger of accidental fall is to be mentioned, which poses high requirements for ductility and mechanical stability of the corresponding material of the surface. If ceramics were used as the material for such a mobile component, for example, a cellular phone or a remote control of a vehicle, there would be the risk of chipping or damaging these components or the surface when the mobile component is dropped. The long-term stability in use in a user's hand or in his pocket or other storage places is not guaranteed with ceramic material. In the present invention, the terms ceramics and ceramic material are used interchangeably.

### SUMMARY OF THE INVENTION

The technical task of the present invention is to overcome the disadvantages described above. In particular, even with high mechanical requirements, such as exist for mobile devices, it is the task of the present invention to be able to provide at least one sensory property of ceramics on the surface of this component. In addition, cost and manufacturing complexity should be reduced.

The features and details that are described in the context of the present inventive production method of course also apply in the context of the inventive adaptation method and the corresponding use of either method and vice versa, so that with respect to disclosure of the individual inventive aspects reference is made, or can be made, reciprocally.

An inventive method is used to produce a surface, in particular a non-ceramic surface, with sensory properties of ceramic on a non-ceramic carrier. Such a method comprises the steps of:
Preparing at least one surface of the substrate,
Coating of the prepared substrate surface with a ceramic-like sensory layer using the vapor-phase deposition method.

In the context of the present invention, under the sensory property of ceramics is to be understood any property which at least partially mediates to a human being with the sensory perception of this non-ceramic surface the impression of ceramics as a material. Sensory properties are therefore properties of a material, which can be perceived by the different senses of a human being. In particular, these are sensory properties that appeal to the touch and vision of a human being. Under these, we preferably understand the contact temperature, surface structure, gloss or color.

An inventive method is based on a vapor-phase deposition to deposit a suitable material for a sensor layer. Here, the vapor-phase deposition can be operated with different basic parameters. In particular, in the context of the present invention both physical and chemical vapor-phase depositions are possible. Suitable materials for the non-ceramic sensor layer are in particular amorphous carbon, zirconium, titanium, copper, nickel, chromium, palladium and ruthenium, as well as combinations of these materials.

The surface of the substrate can be prepared in different ways. On the one hand, preparations can be made for the subsequent gas-phase deposition. This can in particular be made so that the surface of the substrate acquires electrically conductive features. This can be performed, for example, using galvanic coating process. Also the application of a corrosion protective layer may serve for preparing the substrate surface. Due to the fact that as a result of the gas-phase deposition, the substrate surface is substantially represented on the surface of the sensor layer 1:1, the preparation of this substrate surface may also influence the surface structure and the surface gloss. Thus the preparation of the at least one surface of the substrate may be performed by grinding, polishing or other similar process.

An inventive method is used in particular to produce a ceramic-like surface in mobile devices, preferably mobile controls. These preferably include cellular phones, keys, remote vehicle controls or the like.

An inventive method can be further developed to the effect that the process parameters of the vapor-phase deposition method are adapted at least with respect to one of the following sensory characteristics achieved by the method to the corresponding sensory properties of ceramics.
Color
Surface roughness
Surface gloss
Contact temperature
Weight

An adaptation of the preparation process parameters of at least one surface of the substrate can of course also be done to one or more of the above mentioned sensory properties of ceramics. The adaptation can be done individually or in combination. It is advantageous if in each case one of the process parameters of the vapor-phase deposition method and/or the preparation is correlated with the sensory properties of ceramics. Thus, for example, a surface treatment of the substrate surface can influence the surface roughness and/or the surface gloss of the sensor layer. The material and the settings of the process parameters during the vapor-phase deposition method are particularly related to the sensory property of color of the ceramic material. In addition, the layer thickness and the choice of material may adapt the weight and/or the contact temperature as a sensory property of ceramics for the sensor layer.

It is also advantageous if in an inventive method for preparing at least one surface of the substrate at least one of the following steps is performed:
Grinding
Polishing
Matting
Electroplating

The electroplating is effected in particular for preparing an intermediate layer which is electrically conductive. This achieves a preparation for the improved performance of the subsequent vapor-deposition method. Steps such as grinding, polishing or matting, i.e. in particular surface machining of the surface of the substrate preferably relate to adapting with respect to the sensory properties of ceramics related to surface roughness and surface gloss. The production of an electrically conductive intermediate layer is particularly important as a preparation, if the material of the substrate itself comprises non-conducting material. This is for example the case with substrates made of plastic materials.

An inventive method can be further developed to the extent that vapor-phase deposition method is at least one of the following methods:
PVD (Physical Vapor Deposition)
CVD (Chemical Vapor Deposition)
DLC (Diamond Like Carbon)

The DLC method is a special form of the CVD process. So basically the entire list is vapor-phase deposition. The selection of a physical or a chemical vapor-phase deposition method is in particular adapted to the desired sensory property of the ceramic-like surface to be achieved. Of course, different gas-phase deposition methods can also be combined within the scope of the method according to the invention.

It is advantageous if in the inventive method the substrate at least partially consists of plastic and/or, at least partially of metal. Depending on the requirements for the final properties, in particular the sensory properties of the non-ceramic surface, an appropriate selection can be made. The use of plastic reduces the overall weight and, moreover, the cost of a mobile component or mobile operating element produced in this way. If metal is used, the weight can be increased, so that in terms of sensory property of the weight, an adaptation to the appropriate sensory property of ceramics for the mobile device or mobile control element is performed. The achievable surface types in terms of structure and gloss are also adjustable by the selection of the substrate material.

It is also advantageous if in a method according to the invention the coating with a sensor layer is done with a thickness of between about 0.2 μm and 0.5 μm. These thin layers reduce the effort and cost of implementing a method according to the invention. In view of differences in temperature, improved adhesion to the surface of the substrate is achieved with regard to different thermal expansion coefficients of the materials used.

An advantage is further achieved if in a method according to the invention a protective layer is applied under the sensor layer. This protective layer is in particular destined for corrosion protection of the substrate and is useful, for example, in metal and/or plastic materials of the substrate. The protection against corrosion can be effected by chemicals and/or UV light and/or gases. In particular, the protective layer is applied galvanically and comprises nickel and/or copper and/or chromium as a constituent. Of course, it is in principle also possible that an extra layer of protection, for example in the form of a clear coat, is applied outside on the sensor layer.

Another subject of the present invention is a method for adapting a vapor-phase deposition method to produce a ceramic-like finish. The ceramic-like surface is produced with sensory properties of ceramic on a substrate. Such an adaptation method includes the following steps:
Determining a value of at least one sensory property of ceramics,
Adapting at least one process parameter of the vapor-phase deposition method to obtain the value of at least one determined sensory property with a ceramic-like finish.

In principle, the adapting method is thus performed in terms of a comparison between laboratory values and values achievable in production. The relevant process parameters of the vapor-phase deposition method are thus accurately adapted to achieve the specific laboratory values of the respective sensory characteristic of the ceramics. It is quite possible that a reference prototype of the mobile component or the mobile control element is made of ceramic material so that the corresponding values of the sensory properties can be measured directly on these ceramic prototypes. These are, for example, color determination, measurement of the surface roughness, provision of the surface gloss or the determination of the weight. The measuring method for all values is preferably a measuring method which detects this sensory property independently of other parameters. When determining the color value, we may for example use the so-called lab-system, which is independent of the surface structure and the surface gloss of the sensor layer.

The method in accordance with the preceding paragraph may be then further developed in a way that an inventive method for the production of this sensor layer is used for the production of ceramic-like surface on the substrate. The inventive adaptation process thus brings the same benefits, as they have been explained in detail with reference to an inventive production process.

The subject of the present invention is also the use of an adaptation method of the invention and/or the use of a production process of the invention for the manufacture of a mobile component. Such a mobile device is in particular a mobile control. This is preferably a remote control, a remote control key of a vehicle and/or a cellular telephone.

### BRIEF DESCRIPTION OF THE DRAWINGS

Reference is now made more particularly to the drawings, which illustrate the best presently known mode of carrying out the invention and wherein similar reference charac-ters indicate the same parts throughout the views.

FIG. 1 is a substrate at the beginning of an inventive method.

FIG. 2 is a component after the completion of a first embodiment of an inventive method.

FIG. 3 is a n intermediate step in another embodiment of an inventive method.

FIG. 4 is a component of a further embodiment of an inventive method.

### DETAILED DESCRIPTION OF THE DRAWINGS

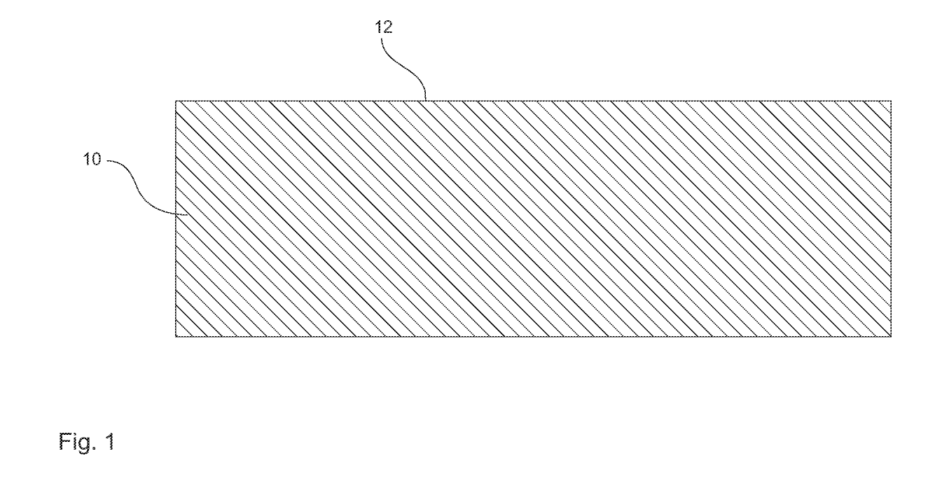

FIG. 1 represents a substrate 10 made of plastic or metal, which comprises a substrate surface 12 at the top. It can be pre-treated using, for example, the electroplating treatment. Also polishing, grinding or matting of this substrate surface 12 is conceivable. Subsequently, for example a sensory layer 20 can be directly applied using the vapor-phase deposition method.

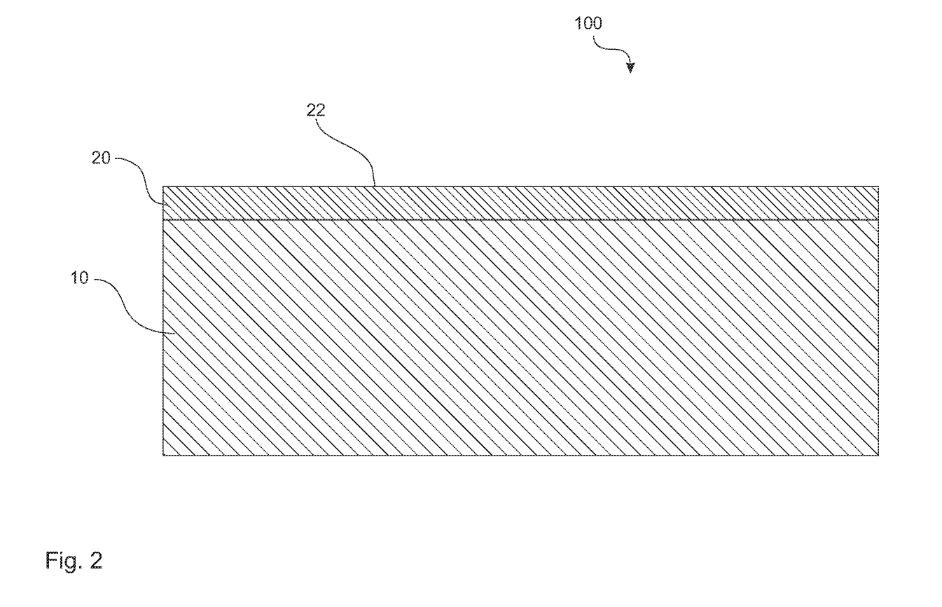

The result of this vapor-phase deposition method is shown in FIG. 2. There, a sensory layer 20 is applied to substrate 10, which has been deposited on the prepared substrate layer 12. The surface 22 of the sensory layer 12 is a ceramic-like surface having at least one of the sensory properties of ceramic material. The sensory properties are here in particular the contact temperature, color, surface structure and/or the surface gloss.

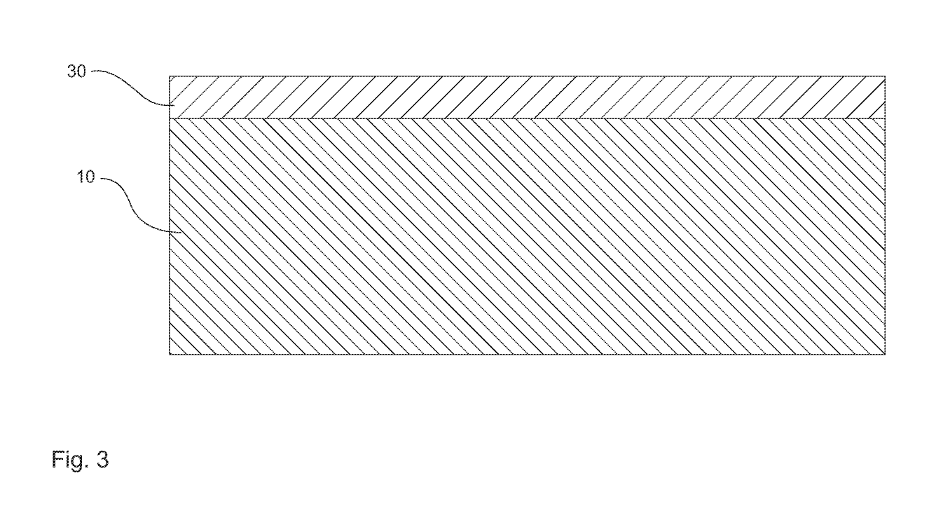

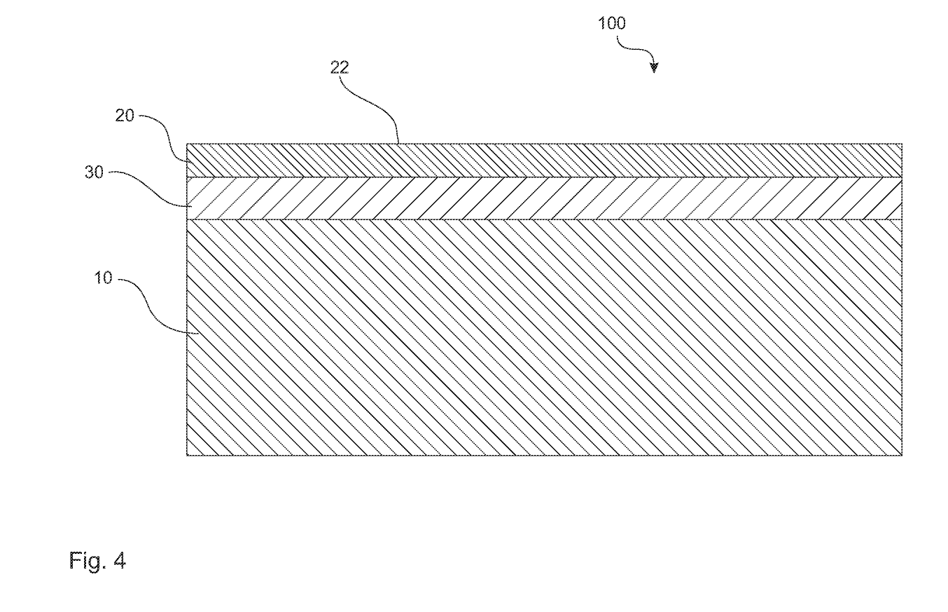

Based on the substrate 10 according to FIG. 1, a protective layer 30 can be applied as is shown in FIG. 3. This protective layer 30 is useful in particular for corrosion protection of substrate 10. Subsequently, using the vapor-phase deposition method, a sensory layer 20 is applied to the protective layer 30 as shown in FIG. 4. Here too, the sensory layer 20 comprises a ceramic-like surface 22, which brings at least one sensory property of the ceramic material.

FIGS. 2 and 4 thus show two differently produced components 100, which can be used for example for mobile control elements.

The foregoing explanation of the embodiments describes the present invention exclusively in the context with the examples. If it is technically useful, the individual features of the embodiments can of course be mutually combined without leaving the scope of the present invention.

### LIST OF REFERENCES

10 Substrate
12 Substrate surface
20 Sensory layer
22 Surface
22 Protective layer
100 Component

1. A method for producing a surface with sensory properties of ceramics on a substrate, comprising the following steps:
preparing at least one surface of the substrate, and
coating of the prepared substrate surface by means of a vapor-phase deposition method with a ceramic-like sensor layer.

2. The method according to claim 1, wherein the process parameters of the vapor-phase deposition method are adapted to at least one of the following corresponding sensory properties of ceramics:
Color
Surface roughness
Surface gloss
Contact temperature
Weight.

3. The method according to claim 1 wherein the step of preparing at least one substrate surface of the substrate includes at least one of the following:
Grinding
Polishing
Matting
Electroplating.

4. The method according to claim 1 wherein the vapor-phase deposition method comprises at least one of the following procedures:
PVD (Physical Vapor Deposition)
CVD (Chemical Vapor Deposition)
DLC (Diamond Like Carbon).

5. The method according to claim 1 wherein the substrate is at least partially made of at least one of plastic and metal.

6. The method according to claim 1 wherein the coating with the sensor layer is made with a layer thickness of between about 0.2 μm and about 0.5 μm.

7. The method according to claim 1 wherein a protective layer is applied under the sensor layer.

8. A method for adapting a vapor-phase deposition method for the production of a surface with sensory properties of ceramics on a substrate, comprising the following steps:
determining a value of at least one sensory property of ceramics,
adapting at least one process parameter of the vapor-phase deposition method to achieve the value of at least one sensory property with a non-ceramic surface.

9. The method according to claim 8, wherein a method with the features of claim 1 is used to produce the surface on the substrate.

10. (canceled)
